(19) United States
(12) Patent Application Publication
(10) Pub. No.: US 2008/0055813 A1
(43) Pub. Date: Mar. 6, 2008

(54) Electrostatic chuck, substrate processing apparatus having the same, and substrate processing method using the same

(75) Inventor: Hyoung-Kyu Son, Sungnam City (KR)

Correspondence Address: KED & ASSOCIATES, LLP, P.O. Box 221200, Chantilly, VA, 20153-1200, US

(73) Assignee: Advanced Display Process Engineering Co., Ltd.

(21) Appl. No.: 11/892,628

(22) Filed: Aug. 24, 2007

(30) Foreign Application Priority Data
Aug. 30, 2006 (KR) 10-2006-0083013

(51) Int. Cl. H01L 21/683; H01L 21/67

(52) U.S. Cl. 361/234

(57) ABSTRACT

An electrostatic chuck includes both a DC power supply and an AC power supply. DC power is supplied to an electrode of the chuck to generate an electrostatic holding force that holds a substrate on the chuck during substrate processing steps. When it is time to remove the substrate from the chuck, the DC power is cut off, and an AC power is applied to help eliminate any residual charge left on the chuck after the DC power has been cut off.

### BACKGROUND

1. Field

The present disclosure relates to an electrostatic chuck, wherein an electrostatic charge on the chuck can be quickly eliminated.

2. Background

A substrate processing apparatus is typically used in various processes used to form semiconductor wafers and liquid crystal displays. Such processing steps can include etching steps, deposition steps and others. A conventional substrate processing apparatus generally includes a chamber where a vacuum state may be formed, a susceptor having a supporting surface capable of supporting a substrate within the chamber, a gas supply line for supplying a processing gas into the chamber, an electric field generator for generating an electric field in the chamber to obtain plasma from the processing gas through discharge, and an exhaust unit for eliminating the processing gas which remains in the chamber after a processing step has been completed.

FIG. 1 is a sectional view showing a conventional substrate processing apparatus 1. The apparatus includes a chamber 10 in which a vacuum atmosphere can be formed to obtain plasma inside the substrate processing apparatus. A substrate support 20 in the chamber 10 supports a substrate S to be processed. The substrate support 20 is installed at a lower portion in the chamber 10 and has a supporting surface capable of supporting the substrate S to be processed. This substrate support 20 also serves as a lower electrode when plasma is generated.

A gas supply line (not shown) is used to supply the inside of the chamber 10 with a processing gas which is used to generate plasma for performing various processing steps Generally, the gas supply line is provided in an upper portion of the chamber 10, whereby the processing gas is supplied from the upper portion thereof. Various diffusion members may also be used to uniformly supply the processing gas into the chamber 10.

An electric field generator generates an electric field required to obtain plasma from the processing gas supplied by the gas supply line. The electric field generator generally has electrodes positioned at upper and lower sides of a space where an electric field is generated. High frequency power is applied to at least one of the electrodes to generate the electric field. Generally, the substrate support 20 functions as a lower electrode while an upper electrode 30 is installed at the upper portion of the chamber 10.

An exhaust unit is used to eliminate the processing gas from the inside of the chamber 10 after it has been used in a processing step. Used processing gas should be completely eliminated in order to avoid affecting the following process steps. Thus, it is important for the exhaust unit to completely exhaust the processing gas.

The substrate processing apparatus 1 further includes an electrostatic chuck 22 on the substrate support 20, as shown in FIG. 2. The electrostatic chuck 22 is used to firmly hold the substrate S on the substrate support 20. The electrostatic chuck 22 is configured so that an electrode 24 is surrounded by a dielectric or electrically insulating member 26, as shown in FIG. 2. The dielectric member 26 is generally made of ceramic, which has excellent plasma-resistance. A power supply line 28 for applying direct current (DC) power to the electrode 24 is connected to the center of the electrode 24. The power supply line 28 is connected to a DC power generator 29 installed outside of the chamber. The applied power generates an electrostatic force which holds the substrate S on the support 20.

In an electrostatic chuck like the one shown in FIG. 2, a residual electric charge may remain on the electrostatic chuck 22 even after the DC power is cut off. The electric charge remaining in the electrode and the glass substrate results in a residual electrostatic force that tends to hold the substrate S. This force can cause the substrate to be broken when one attempts to remove the substrate S from the chuck.

### BRIEF DESCRIPTION OF THE DRAWINGS

The embodiments will be described in detail with reference to the following drawings, in which like reference numerals refer to like elements, and wherein:

FIG. 1 is a side view showing a conventional substrate processing apparatus;

FIG. 2 is a side view showing a conventional electrostatic chuck;

FIG. 3 is a side view showing a first embodiment of an improved electrostatic chuck;

FIG. 4 is a graph showing an amplitude of power applied to the electrostatic chuck shown in FIG. 3;

FIG. 5 is a side view showing a substrate processing apparatus having the electrostatic chuck shown in FIG. 3; and

FIG. 6 is a flowchart illustrating a method of processing a substrate.

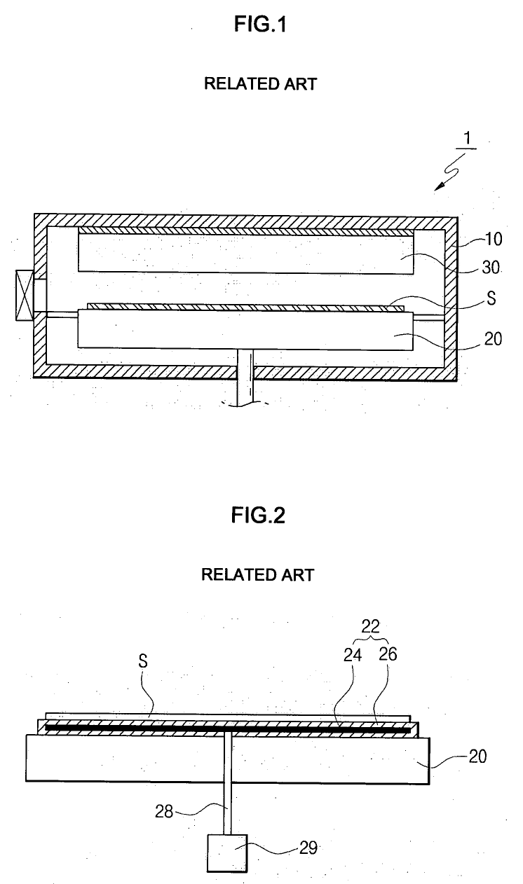

### DETAILED DESCRIPTION

Hereinafter, a preferred embodiment according to the present invention will be described in detail with reference to the drawings. Throughout the drawings, like reference numerals are used to designate like elements.

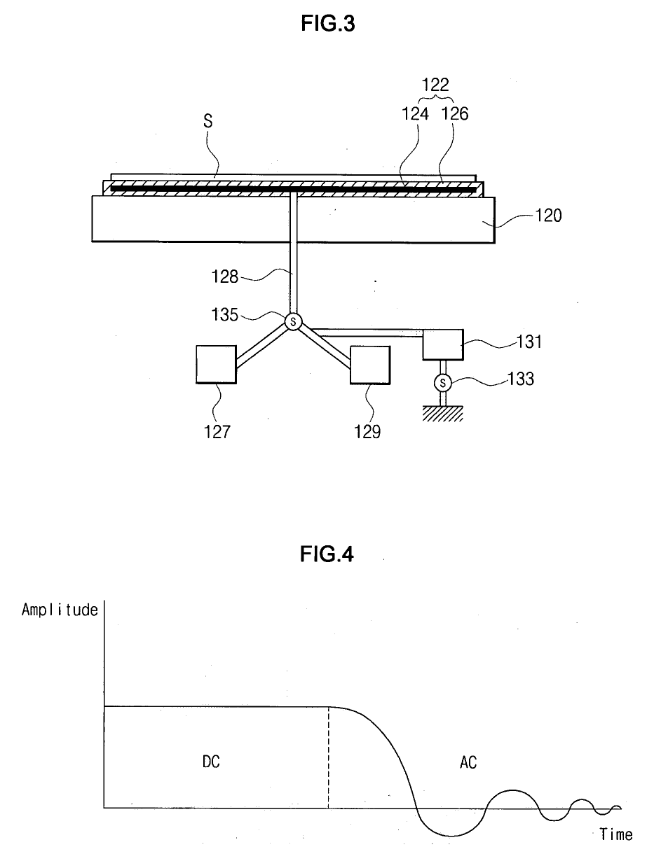

As shown in FIG. 3, an electrostatic chuck 122 according to an embodiment of the present invention includes an electrode 124, a dielectric member 126, a DC power supply 127, and an AC power supply 129.

The AC power supply 129 is used to supply AC power to the electrode 124 after processing steps have been completed and it is time to remove the substrate S from the chuck 122. In a first embodiment, when it is time to remove the substrate from the chuck 122, the supply of DC power from the DC power supply 127 is cut off and simultaneously the AC power supply 129 is activated to supply the AC power to the electrode 124.

In some embodiments, the AC power supply 129 may be an AC voltage supply or an AC pulse generator. The AC power supply 129 may be selectively used depending on the properties of any residual electric charge which remains in the electrostatic chuck after the DC power supply has been cut off.

If the DC power 127 supply had applied a positive DC voltage to the chuck during the substrate processing steps, and then AC power, where the voltage switches back and forth between negative and positive, is applied to the electrode 124 of the chuck 122 after the processing steps are complete, any residual positive charge left from the application of the positive DC voltage will quickly dissipate. Similarly, if the DC power supply 127 had applied a negative DC voltage to the electrode 124 of the chuck 122 during the processing steps, application of an AC voltage to the electrode 124 will quickly dissipate any residual negative charge remaining on the electrode 124. That is, the applied AC power causes any residual electric charge remaining in the electrostatic chuck 122 to be neutralized. This, in turn, eliminates any residual electrostatic force tending to hold the substrate on the chuck 122. Thus, the substrate S can be easily and safely detached from the electrostatic chuck 122, eliminating the problem of breakage which could be caused by a residual attractive force.

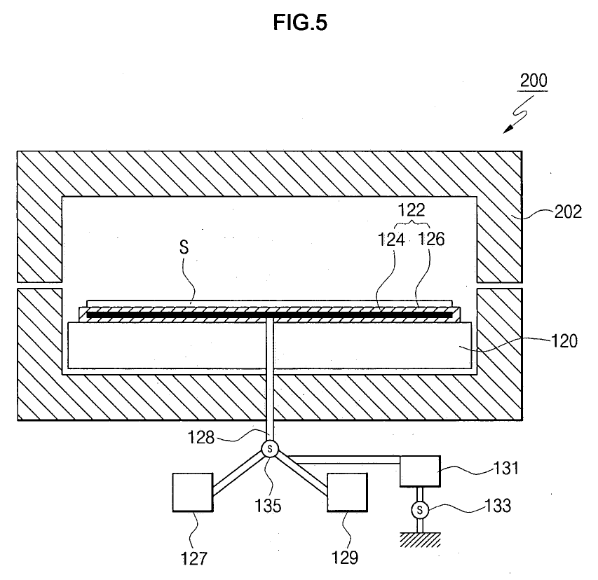

FIG. 4 shows a waveform of the voltage applied to the electrostatic chuck 122. As shown in FIG. 4, initially a positive DC voltage is applied to the electrode 124 to generate an electrostatic holding force. Once the processing steps are complete, the AC power initially supplied from the AC power supply 129 preferably has the same amplitude and polarity as the DC power supplied from the DC power supply 127. Then, it is preferable to eliminate any residual electric charge from the chuck by quickly by reducing the amplitude of the AC power supplied from the AC power supply 129.

As can be seen in FIG. 4, the AC voltage applied to the electrode 124 quickly goes negative, which helps to eliminate any residual positive charge on the electrode which resulted from the application of the DC voltage. Also note that the amplitude of the AC voltage is quickly reduced to zero. Both of these factors help to ensure that any residual charge on the electrode of the electrostatic chuck is quickly removed.

In some embodiments, a voltage sensor, or more generally, an electric charge detecting sensor 131, can be used to detect a residual electric charge left on the electrode of the chuck. Detecting the residual electric charge with the sensor 131 prevents more power than is necessary from being supplied by the AC power supply. Instead, the sensor 131 is used to adjust the amount of AC power applied by the AC power supply 129 so that only the AC voltage required to neutralize the remaining residual electric charge is applied to the electrode 124 when the DC power supply 127 is shut off.

The sensor 131 may also be used to confirm whether the electrode is completely neutralized as the AC power is supplied. If the residual charge on the electrode 124 is not neutralized, additional AC power can be supplied through the AC power supply 129 to neutralize the electrode 124.

Embodiments of the electrostatic chuck 122 may further include a control unit (not shown) for controlling the DC power supply 127 and the AC power supply 129. As described above, when a process of electrostatically adsorbing a substrate is terminated, the control unit would cut off the DC power and simultaneously operate the AC power supply 129 to supply the AC power to the electrode to eliminate any residual electric charge. The control unit would rapidly decrease the amplitude of the AC power supplied from the AC power supply 129 to rapidly eliminate the residual electric charge remaining on the chuck 122.

The sensor 131 can be grounded via a first switch 133. The switch would control the grounded and non-grounded states of the multi-tester. The switch 133 could also be used to ground the electrode, which would be another way of reducing or neutralizing any residual charge on the electrode 124. Grounding could be used instead of the above-described method in which AC power is supplied through the AC power supply 129 after the DC power is cut off. The grounding method and/or the method of using the AC power supply 129 may be selectively or concurrently used, as desirable.

In addition, the power supply line 128 running to the electrode 124 could be provided with a second switch 135. The second switch 135 would be used to control the application of the DC power and the AC power to the electrode 124. For example, when the electrostatic holding force is to be generated, the AC power supply 129 may be cut off so that only the DC power supply 127 supplies DC power to the electrode. When it is desirable to neutralize the electrostatic holding force, the second switch 135 could supply the AC power from the AC power supply 129 and the DC power supply 127 may be cut off. Further, when it is desirable to supply both DC and AC power together, the second switch 135 can serve to adjust the amplitude of the supplied power.

When it is time to remove the electrostatic holding force, the second switch 135 can be used together with the first switch 133 to eliminate some or all of the residual electric charge on the chuck 122 by grounding the electrode 124 before the AC power supply 129 supplies AC power. This allows some or all of the residual electric charge to be reduced naturally, without the need to supply artificial AC electric power.

FIG. 5 shows a substrate processing apparatus that includes an electrostatic chuck apparatus as described above. As shown therein, a substrate processing apparatus 200 includes a chamber 202 for processing a substrate. The electrostatic chuck 122 is installed within the chamber 202.

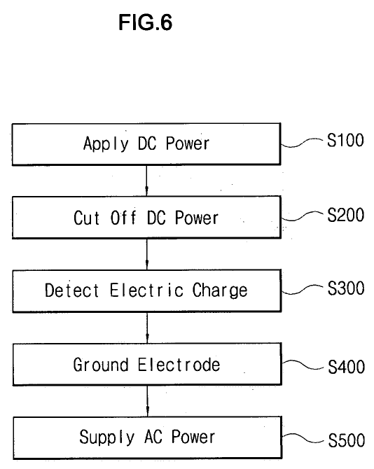

A method of using the processing apparatus shown in FIG. 5 will now be described with reference to FIG. 6. In step S100 DC power is applied to generate an electrostatic holding force that holds the substrate on the chuck 122. In step S200, once the substrate processing is complete, the DC power is cut off. In step S300, the sensor is used to detect an electric charge on the chuck. In step S400 the electrode of the chuck is grounded to eliminate some or all of the charge on the chuck. Then, in step S500, AC power is supplied to the chuck to further eliminate any residual charge on the chuck.

Steps S300 and S400 are optional. Thus, in some embodiments, the method may proceed from step S200 directly to step S500. Further, in some embodiments, only step S400 may be skipped. In other words, in some embodiments, the detection step may be performed, and then the method could proceed directly to step S500. Finally, in some embodiments, the detecting step may not be performed. In other words, the method may proceed from step S200 directly to step S400.

Step S300 of detecting the electric charge can be used as a part of a method for adjusting the electric charge of the AC power supplied to neutralize the remaining electric charge in step S500. That is, the remaining electric charge is exactly detected by means of a sensor, so that only the AC power required to neutralize the remaining electric charge is supplied, thereby preventing unnecessary power consumption.

In an electrostatic chuck as described above, when the DC power is cut off, any residual electric charge on the chuck can be quickly eliminated by applying AC power to the chuck. Thus, the time required to eliminate the residual electric charge from an electrostatic chuck so that the substrate can be safely removed is considerably reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although a number of illustrative embodiments have been described, it should be understood that numerous other modifications and embodiments can be devised by those skilled in the art that will fall within the spirit and scope of the principles of this disclosure. More particularly, various variations and modifications are possible in the component parts and/or arrangements which would fall within the scope of the disclosure, the drawings and the appended claims. In addition to variations and modifications in the component parts and/or arrangements, alternative uses will also be apparent to those skilled in the art.

What is claimed is:

1. An electrostatic chuck, comprising:
an electrode;
a DC power supply that applies DC power to the electrode to generate an electrostatic holding force; and
an AC power supply that applies AC power to the electrode to neutralize a residual electric charge remaining on the electrode when the DC power supply is shut off.

2. The chuck according to claim 1, wherein the AC power supply is an AC voltage supply.

3. The chuck according to claim 1, wherein the AC power supply is a pulse generator.

4. The chuck according to claim 1, further comprising a sensor that detects a charge on the electrode.

5. The chuck according to claim 1, further comprising a voltage sensor that detects a voltage of the electrode.

6. The chuck according to claim 5, wherein the voltage detector is grounded.

7. The chuck according to claim 6, further comprising a switch located between the voltage detector and ground.

8. The chuck according to claim 7, further comprising a switch that couples the electrode to the DC power supply and the AC power supply.

9. The chuck according to claim 1, further comprising a switch that couples the electrode to the DC power supply and the AC power supply.

10. A substrate processing apparatus, comprising:
a substrate processing chamber;
an electrostatic chuck mounted in the substrate processing chamber;
a DC power supply that applies DC power to an electrode of the electrostatic chuck to generate an electrostatic holding force; and
an AC power supply that applies AC power to the electrode to neutralize a residual electric charge remaining on the electrode when the DC power supply is shut off.

11. The apparatus according to claim 10, wherein the AC power supply is an AC voltage supply.

12. The apparatus according to claim 10, wherein the AC power supply is a pulse generator.

13. The apparatus according to claim 10, further comprising a sensor for detecting an electric charge on the electrode.

14. The apparatus according to claim 13, wherein the sensor comprises a voltage sensor.

15. The apparatus according to claim 13, wherein the sensor is grounded.

16. A method of processing a substrate located on an electrostatic chuck, comprising:
applying DC power to an electrode of the electrostatic chuck to generate an electrostatic holding force that holds the substrate on the chuck;
conducting processing steps on the substrate;
cutting off the DC power when it is time to remove the substrate from the chuck; and
supplying AC power to the electrode to neutralize a residual electric charge remaining on the chuck after the DC power is cut off.

17. The method according to claim 16, further comprising grounding the electrode after the DC power is cut off and before the AC power is supplied.

18. The method of claim 17, further comprising detecting the residual charge on the electrode after the electrode has been grounded, and wherein supplying AC power to the electrode comprises applying only the AC power required to neutralize the electric charge detected during the detecting step.

19. The method according to claim 16, further comprising detecting an electric charge on the electrode after the DC power is cut off.

20. The method according to claim 16, wherein the step of applying AC power to the electrode comprises applying only the AC power required to neutralize the electric charge detected during the detecting step.

21. The method of claim 16, wherein the step of supplying AC power to the electrode comprises:
initially applying an AC voltage having substantially the same polarity and amplitude as the DC voltage; and
quickly reducing the amplitude of the AC voltage to zero.
